(19) United States
(12) Patent Application Publication
(10) Pub. No.: US 2004/0152331 A1
(43) Pub. Date: Aug. 5, 2004

(54) Process for etching polysilicon gates with good mask selectivity, critical dimension control, and cleanliness

(75) Inventors: Songlin Xu, Fremont, CA (US); Thorsten B. Lill, Santa Clara, CA (US); Yeajer Arthur Chen, Fremont, CA (US); Mohit Jain, San Jose, CA (US); Nicolas Gani, Milpitas, CA (US); Shing-Li Sung, Hsin-Chu (TW); Jitske K. Kretz, San Jose, CA (US); Meihua Shen, Fremont, CA (US); Farid Abooameri, Pleasanton, CA (US)

Correspondence Address: PATENT COUNSEL, APPLIED MATERIALS, INC., Legal Affairs Department, P.O. Box 450A, Santa Clara, CA, 95052, US

(73) Assignee: Applied Materials, Inc.

(21) Appl. No.: 10/660,151

(22) Filed: Sep. 11, 2003

Related U.S. Application Data
(60) Provisional application No. 60/444,340, filed on Jan. 31, 2003.

(51) Int. Cl. H01L 21/3205; H01L 21/4763

(52) U.S. Cl. 438/719

(57) ABSTRACT

The present invention provides a process of etching polysilicon gates using a silicon dioxide hard mask. The process includes exposing a substrate with a polysilicon layer formed thereon to a plasma of a process gas, which includes a base gas and an additive gas. The base gas includes HBr, Cl₂, O₂, and the additive gas is NF₃ and/or N₂. By changing a volumetric flow ratio of the additive gas to the base gas, the etch rate selectivity of polysilicon to silicon dioxide may be increased, which allows for a thinner hard mask, better protection of the gate oxide layer, and better endpoint definition and control. Additionally, when the polysilicon layer includes both N-doped and P-doped regions, the additive gas includes both NF₃ and N₂, and by changing a volumetric flow ratio of NF₃ to N₂, the etching process may be tailored to provide optimal results in N/P loading and microloading.

### CROSS REFERENCE TO RELATED APPLICATIONS

The present application claims priority to Provisional Patent Application Serial No. 60/444,340 filed on Jan. 31, 2003.

### FIELD OF THE INVENTION

The present invention pertains to semiconductor processing. More particularly, the present invention pertains to a process for etching polysilicon gates.

### BACKGROUND OF THE INVENTION

Gate etching is a critical step in integrated circuit (IC) manufacturing. To form polysilicon gates on a substrate, a polysilicon layer is deposited over a thin layer of gate oxide on the substrate and a mask made of a masking material such as photoresist is formed over the polysilicon layer to define the gates to be etched. During gate etching, the substrate is exposed to an energized process gas in a plasma chamber. Conventional polysilicon etching processes often use a Cl₂/HBr/O₂ process gas. These processes can lead to well defined structures when the gate size is on the order of 0.18 μm or above and when the masking material is photoresist. For sub-0.10 μm devices, however, a hard mask made of silicon dioxide is often used for polysilicon gate etching to obtain better critical dimension control. In these circumstances, conventional polysilicon etching processes have been found to be ineffective in producing satisfactory etching results.

One problem with conventional polysilicon gate etching processes is the difficulty in obtaining sufficient sidewall passivation when a hard mask is used. Without enough sidewall passivation, lateral as well as vertical etching may occur, resulting in large changes in the critical dimension (CD) of a feature as a result of an etching process. Such changes are referred to as CD bias.

Still another problem with conventional polysilicon gate etching processes is the need for frequent cleaning of inner parts of the plasma chamber in order to remove etch residues condensed or deposited thereon during the polysilicon etching processes. The chemical compositions of the etch residues vary depending on the composition of the process gas and the layers of materials on the substrate that are exposed to the plasma. The chemical compositions of the etch residues also vary considerably across surfaces in the plasma chamber. Typically, the etch residues are composed of polymeric and silicon containing species resulting from reactions among species in the plasma and between the plasma and surface materials in the plasma chamber. Since these etch residues may flake off the chamber and cause contamination of the substrate, periodic chamber cleaning is performed to remove the etch residues. Chamber cleaning is a time consuming and labor intensive process. It also causes interruption of normal production flow and sometimes erosion of chamber parts and components, which are usually expensive to replace. Therefore, a “dirty” polysilicon etching process that raises the need for frequent chamber cleaning is usually not desirable.

To overcome the dirty chamber problem, CF₄ has been added to the HBr/Cl₂/O₂ chemistry in some conventional polysilicon etching processes. But adding CF₄ often degrades etching selectivities associated with the polysilicon etching processes. The term “selectivity” is used to refer to the ratio of the etch rate of one material to that of another material also exposed to the plasma. As the hard mask is usually much thinner than the photoresist mask, a poor etching selectivity of polysilicon to the hard mask may result in the hard mask being consumed before completion of the polysilicon etching process. Similarly, a poor selectivity of polysilicon to the thin gate oxide layer may result in punch through of the gate oxide during the polysilicon etching process. Once the gate oxide is punched through, rapid etching of the semiconductor substrate may follow, making the etching process a total failure.

A further problem with conventional polysilicon gate etching processes is the difficulty in etching dual-doped gates. Dual-doped polysilicon gates are used in complimentary metal-oxide-semiconcutor (CMOS) integrated circuits having both N-channel and P-channel metal-oxide-semiconductor field effect transistor (MOSFET) devices. The gates for the N-channel MOSFETS are heavily doped with N-type dopants and the gates for the P-channel MOSFETS are heavily doped with P-type dopants. The dual-doped gates can be fabricated by doping selected regions of the polysilicon layer with N-type and P-type dopants and then etching the N-type gates and the P-type gates simultaneously using a plasma etching process.

The dual-doped gates are difficult to etch because regions with different dopings may react differently with the plasma, resulting in different etch rates, different etching profiles, and different etching selectivities. For example, the N-doped polysilicon regions are typically etched 20% faster than the P-doped regions when the two regions are etched simultaneously. This difference in etch rates can lead to residues depositing in the more slowly etched regions and/or exessive gate oxide loss in the more rapidly etched regions. The difference in etching profiles often shows up as variations in angles made by sidewalls of etched features with a plane of the substrate. More than 3 degrees of this angular difference has been observed from conventional polysilicon etching processes. This angular difference results in variations in the critical dimensions of etched polysilicon gates across the substrate, which is not tolerable when fabricating ICs having sub-0.10 μm devices. The difference in etch rates, etching profiles, CD bias, or etching selectivities between N-doped and P-doped regions is often referred to as N/P loading.

An additional problem with conventional polysilicon etching processes is the problem of microloading, which is a measure of the difference in etch rates between areas having densely-packed line and space patterns and areas with isolated line patterns. Microloading can be a result of an increased load on the etching process in areas where a greater volume of material is removed, or it can be a result of different aspect ratios of etched features caused by the difference in the mask patterns. A significant amount of microloading is undesirable because it means that significant amount of overetching has to be done in order to be certain that the gates in areas having different pattern densities are all fully formed. Excessive overetching creates the danger of punching through the gate oxide layer.

### SUMMARY OF THE INVENTION

The present invention provides a process of etching polysilicon gates using a silicon dioxide hard mask. In one embodiment of the present invention, a polysilicon layer is formed on a silicon substrate, a thin gate oxide layer lies under the polysilicon layer, and a silicon dioxide hard mask is formed over the polysilicon layer to define the gates to be etched. The substrate is placed in a process chamber, and exposed to a plasma of a process gas, which includes a base gas and an additive gas. The base gas includes HBr, Cl₂, O₂, and the additive gas is NF₃ and/or N₂. By changing a volumetric flow ratio of the additive gas to the base gas, the etch rate selectivity of polysilicon to silicon dioxide may be increased, which allows for a thinner hard mask, better protection of the gate oxide layer, and better endpoint definition and control. The presence of the additive gas also helps with simultaneous removal of etch residues on chamber walls during the polysilicon etching process, leading to a cleaner process and less frequent need for chamber cleaning. Additionally, when the additive gas includes both NF₃ and N₂, by changing a volumetric flow ratio of NF₃ to N₂, the etching process may be tailored to provide optimal results in N/P loading and microloading.

### BRIEF DESCRIPTION OF THE DRAWINGS

FIG. 1a is a schematic cross-sectional view of a masked polysilicon layer on a substrate according to one embodiment of the present invention.

FIG. 1b is a schematic cross-sectional view of a plurality of polysilicon gates formed in the polysilicon layer according to one embodiment of the present invention.

FIG. 1c is a schematic cross-sectional view of a masked dual-doped polysilicon layer having P-doped and N-doped regions on a substrate according to one embodiment of the present invention.

FIG. 1d is a schematic cross-sectional view of a plurality of polysilicon gates formed in the dual-doped polysilicon layer according to one embodiment of the present invention.

FIG. 1e is a schematic cross-sectional view of a masked polysilicon layer wherein doping concentrations vary vertically.

FIG. 1f is another schematic cross-sectional view of a masked polysilicon layer wherein doping concentrations vary vertically.

FIG. 1g is a flowchart illustrating a plurality of etch steps in the polysilicon etching process according to one embodiment of the present invention.

FIG. 2a is a schematic diagram of an illustrative etching system that may be used in connection with the embodiments of the invention.

FIG. 2b is a flowchart illustrating a method of performing an etch step in the polysilicon etching process in the illustrative etching system according to one embodiment of the present invention.

FIGS. 3a-3e is a schematic cross-sectional view of a plurality of etched polysilicon lines illustrating problems of undercutting, reentrant profile, tapered sidewalls, notching, and sidewall profile transition, respectively, during a polysilicon etching process.

### DETAILED DESCRIPTION OF THE INVENTION

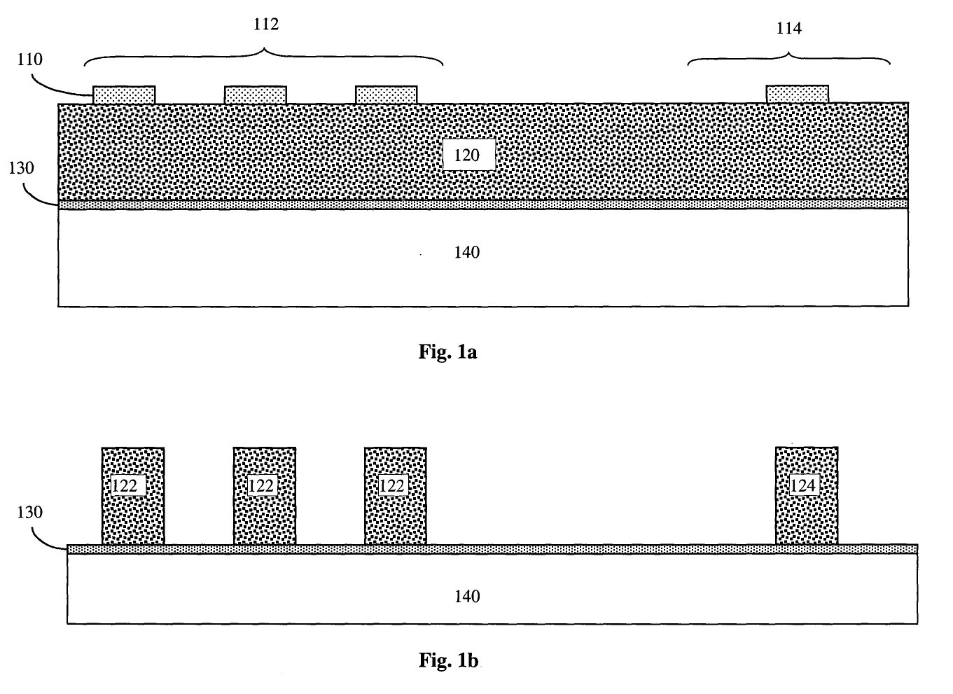

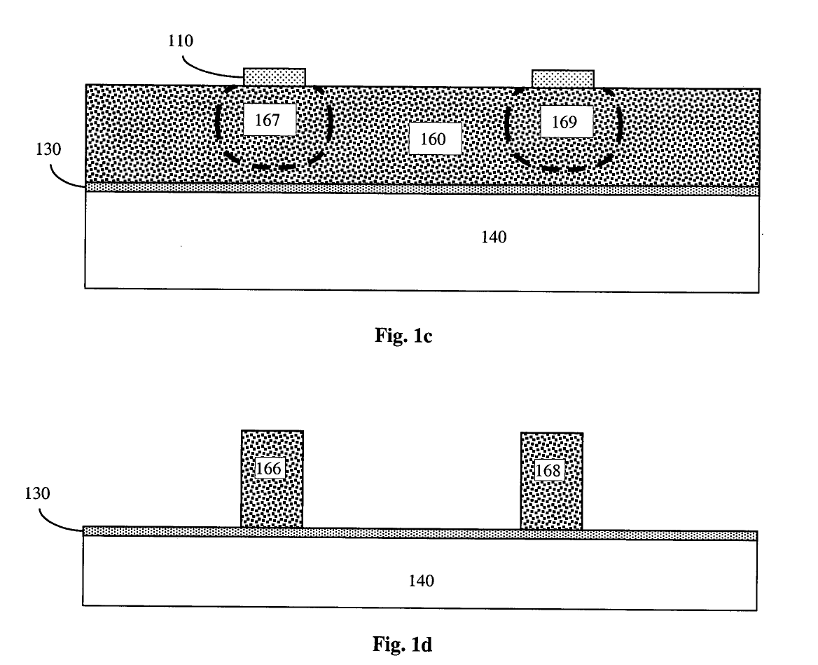

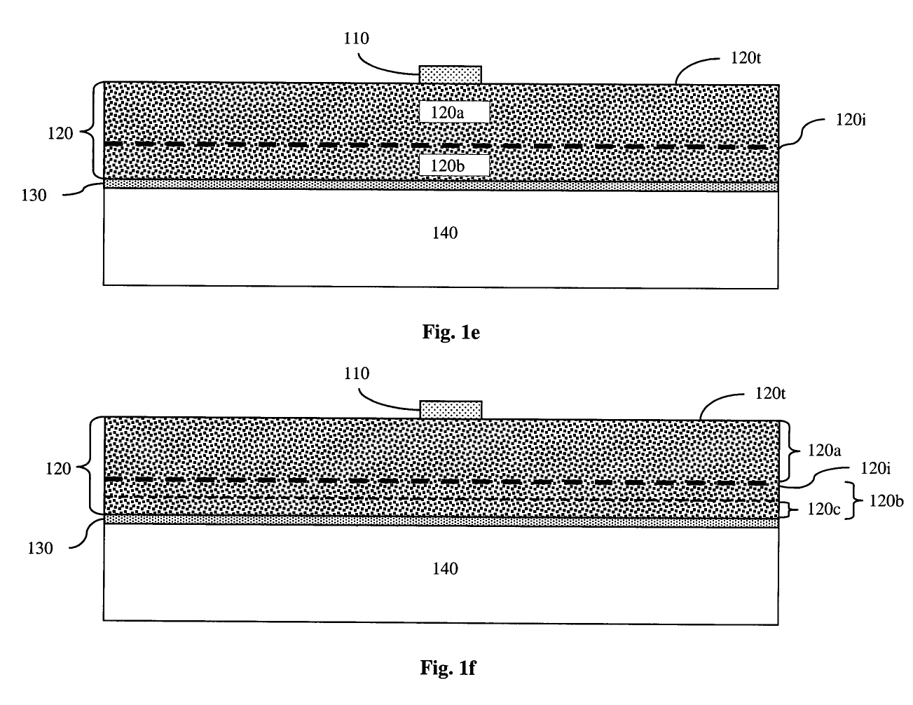

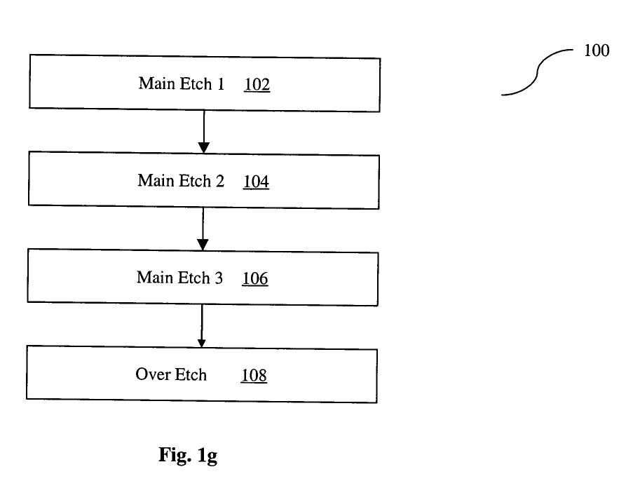

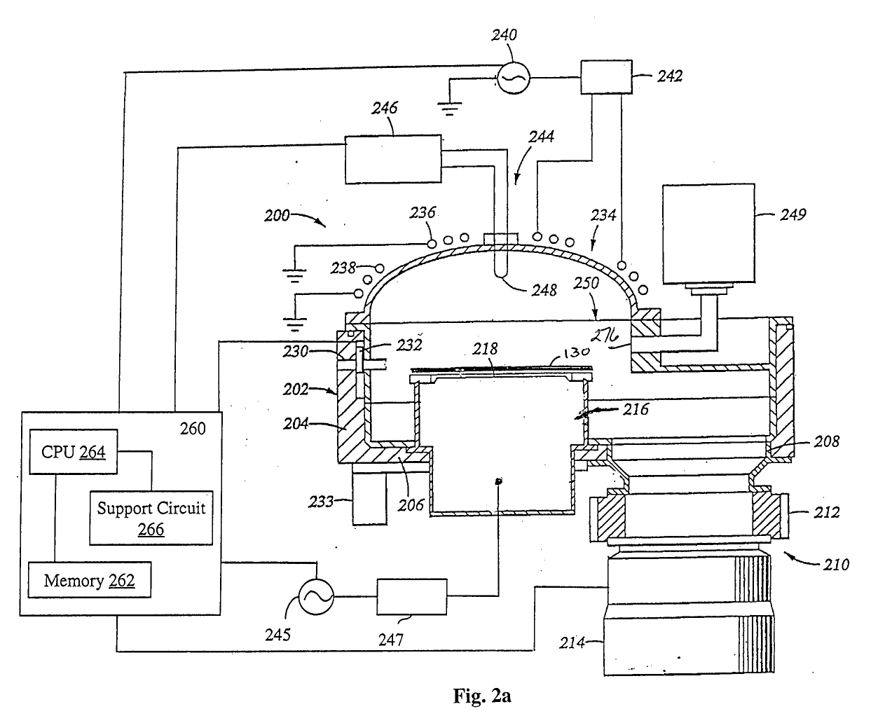

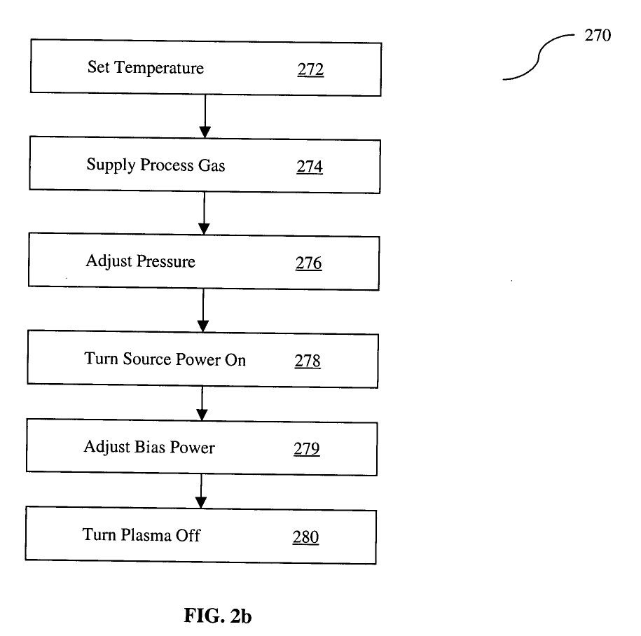

The present invention includes a polysilicon gate etching process. FIG. 1a illustrates a polysilicon layer 120 on a semiconductor substrate 140 according to one embodiment of the present invention. A thin gate oxide layer 130 lies under the polysilicon layer 120 and a hard mask 110 is formed over the polysilicon layer 120. The hard mask includes a variety of patterns, such as a densely packed line and space pattern 112 and an isolated line pattern 114, which are used to define a plurality of closely spaced polysilicon gates 122 and an isolated polysilicon gate 124, respectively, that can be formed using the process of the present invention, as illustrated in FIG. 2b.

The process of the present invention is also useful for etching dual-doped polysilicon layer 160, as shown in FIG. 1c. The dual-doped polysilicon layer 160 includes N-doped regions 167 and P-doped regions 169. The hard mask 170 includes patterns that define the gates to be etched, including an N-doped gate 166 and a P-doped gate 168, as shown in FIG. 1d. The N-doped gate 166 and P-doped gate 168 may be electrically connected by being parts of a single polysilicon line, or they may be in two separate polysilicon lines.

The polysilicon layer 120 or 160 is etched by exposing the substrate 140 to an etching plasma. The plasma is usually generated by energizing a process gas in a plasma reactor, such as, for example, a decoupled plasma source (DPS) reactor, or a DPS II reactor, both being available from Applied Materials, Inc., in Santa Clara, Calif. A schematic diagram of the DPS II reactor is shown in FIG. 2A. The DPS II reactor is also disclosed in U.S. patent application Ser. No. 09/611,817 filed on Jul. 7, 2000, and also in U.S. patent application Ser. No. 09/544,377 filed on Apr. 6, 2000, both being incorporated by reference herein.

Referring to FIG. 2A, the DPS II reactor (reactor) 200 includes a process chamber (chamber) 202 having a chamber wall 204 and a chamber bottom 206. The chamber wall 204 extends substantially perpendicularly from the edge of the chamber bottom 206. The chamber bottom 206 includes an outlet 208 for exhausting gases from the chamber. An exhaust system 210 is attached to the outlet 208 of the chamber bottom 206. The exhaust system 210 may include a throttle valve 212 and a vacuum pump 214. A variety of commercially available valves and pumps may be utilized in the exhaust system 210, and the outlet 208 may comprise a removable outlet to accommodate attachment of particular valves.

A substrate support 216 is also disposed on the chamber bottom 206. The substrate support 216 may be an electrostatic chuck, a vacuum chuck or other wafer holding mechanism, and includes a substrate supporting surface 218 on which the wafer or substrate 140 can be placed for processing. The substrate supporting surface 218 may be thermally connected to a substrate temperature control system (not shown), such as a resistive heating coil and/or fluid passages connected to a heating or cooling fluid system. The substrate support also includes a substrate lift mechanism (not shown) for facilitating substrate transfers onto and off the substrate support 216.

A slit 230 for facilitating substrate transfers into and out of the chamber is disposed on the chamber wall 204 at a position proximate the substrate support 216 and above the substrate supporting surface 218. A slit valve 232 attached to a slit valve actuator 233 is disposed adjacent the slit 230 to facilitate substrate transfers into and out of the chamber 202.

A chamber lid 234 is sealingly disposed above the chamber wall 204 to provide an enclosed environment inside the chamber for vacuum processing. The lid 234 may be removable or hinged to a portion of the chamber wall 204. The chamber lid may be shaped as a plate or a dome depending on the process for which the chamber is configured and the desired processing parameters. In the embodiment shown in FIG. 2A, the chamber lid is dome-shaped. A coil antenna comprising one or more RF coils is wound around the dome-shaped lid. In the embodiment shown in FIG. 2A, two coil loops 236, 238 are wound around a common axis of symmetry coincident with the axis of symmetry of the dome-shaped lid 234 and the axis of symmetry of the substrate supporting surface 218. The first RF coil 238 is wound around a bottom portion of the dome-shaped lid 234 while the second RF coil 236 is positioned centrally above the lid 234.

The first and second RF coils 236, 238 are connected to a first RF power supply (source power) 240 through an RF power distribution network 242. Optionally, an RF impedance match network (not shown) may be connected between the RF power source 240 and the RF power distribution network 242. A second RF power supply (bias power) 245 is connected to the substrate support 216 through an RF impedance match network 247.

A gas distributor 244 is fluidly connected to a gas source 246 containing various gaseous components. As shown in FIG. 2, the gas distributor 244 may include one or more gas injection nozzles 248 disposed through a central top portion of the chamber lid 234. Optionally, a remote plasma source 249 may be fluidly connected to introduce a remote plasma, such as a chamber cleaning plasma, through a corresponding opening 276 into chamber 202.

The reactor 200 further includes a liner 250 removably disposed in the chamber 202. The liner 250 configures the chamber for particular processing, such as an etch process. The liner 250 is made of nickel, aluminum, or other metals or metal alloys appropriate for plasma processing, and may also include an anodized aluminum surface. The liner 250 may be a single piece construction or a multi-piece construction.

When reactor 200 is used to perform the polysilicon etching process, the substrate 140 is placed on the substrate supporting surface 218 and gaseous components are introduced into the chamber 202 through gas injection nozzle 248 to form a process gas in the chamber 202. A volumetric flow rate of each gaseous component in the process gas may be individually controlled by the gas distributor 244. Gas pressure in the chamber 202 is controlled using the vacuum pump 214 and the throttle valve 212. A plasma is ignited in the chamber 202 by turning on the source power 240. The bias power 245 may be adjusted to obtain a proper level of electrical bias between the substrate 130 and the plasma.

A controller 260 comprising a central processing unit (CPU) 264, a memory 262, and support circuits 266 for the CPU 264 is coupled to the various components of the reactor 200 to facilitate control of the polysilicon etching process of the present invention. The memory 262 can be any computer-readable medium, such as random access memory (RAM), read only memory (ROM), floppy disk, hard disk, or any other form of digital storage, local or remote to the reactor 200 or CPU 264. The support circuits 266 are coupled to the CPU 264 for supporting the CPU in a conventional manner. These circuits include cache, power supplies, clock circuits, input/output circuitry and subsystems, and the like.

FIG. 2A only shows one illustrative configuration of various types of plasma reactors that can be used to practice the present invention, including, for example, inductively coupled plasma (ICP) reactors, electron-cyclotron reactors (ECR), triode reactors, and the like.

As shown in FIG. 1g, in one embodiment of the present invention, the polysilicon etching process 100 includes a first main etch step (ME1) 102, an optional second main etch step (ME2) 104, an optional third main etch step (ME3) 106 and an over etch step (OE) 108. The first, the second, and/or the third main etch steps 102/104 etch the polysilicon layer 120 until portions of the gate oxide layer 130 become exposed to the plasma. Thereafter, the over etch step 108 is performed until the polysilicon gates are fully formed. The over etch step has a higher etching selectivity to oxide than the first, the second, or the third main etch step. So, by using the over etch step to complete the etching of the polysilicon gates, the gate oxide is less likely to be punched through by the polysilicon etching process.

FIG. 2B is a flow chart illustrating a process sequence 270 for performing each etch step in the process 100 using the reactor 200, according to one embodiment of the present invention. The sequence 270 includes step 272, in which the substrate temperature is set and further maintained at a predetermined value by controlling the flow of the backside helium gas.

The sequence 270 further includes step 274, in which gaseous components are supplied into the process chamber 202 to form the process gas. The sequence 270 further includes step 276, in which the pressure of the process gas in the process chamber 202 is adjusted by regulating a position of the throttle valve 212.

The sequence 270 further includes step 278, in which the source power 240 is adjusted to a proper level to maintain a plasma of the process gas in processing chamber 202. Thereafter or about simultaneously with adjusting the source power, at step 279 in the process sequence 270, the RF bias power 245 is adjusted to maintain a proper electrical bias of the wafer support pedestal with respect to the plasma. Depending on the magnitude of RF bias power, a significant DC electrical potential difference (or DC voltage) may exist between the plasma and the wafer support 216, and most of this DC voltage appears across a thin sheath region near the substrate 140. Positive ions coming from the plasma are thus accelerated in the sheath region, and impinge on the substrate 140 with a significant amount of energy and directionality. The energetic and directional ions facilitate anisotropic etching. When such anisotropy is not required or when high energy ion impingement is not desired, as sometimes occurs during the over etch step, the RF bias power may be set at a low value or completely turned off during the plasma process.

After the substrate 140 has been exposed to the plasma for a predetermined process time, or after a conventional endpoint detector indicates enough processing has been performed, the plasma is turned off at step 280 by turning off the source power 240 and the bias power 245. Sometimes, at the completion of an etch step, if there is a subsequent etch step in the process 100, the source power 240 and the bias power 245 are not completely turned off, but are adjusted to the levels proper for the subsequent etch step.

The foregoing steps of the sequence 270 need not be performed sequentially, e.g., some or all of the steps may be performed simultaneously or in different order. In one embodiment of the present invention, sequence 270 is performed by the controller 260 as shown in FIG. 2A according to program instructions stored in memory 262. Alternatively, some or all of the steps in the sequence 270 may be performed in hardware such as an application-specific integrated circuit (ASIC) or other type of hardware implementation, or a combination of software or hardware.

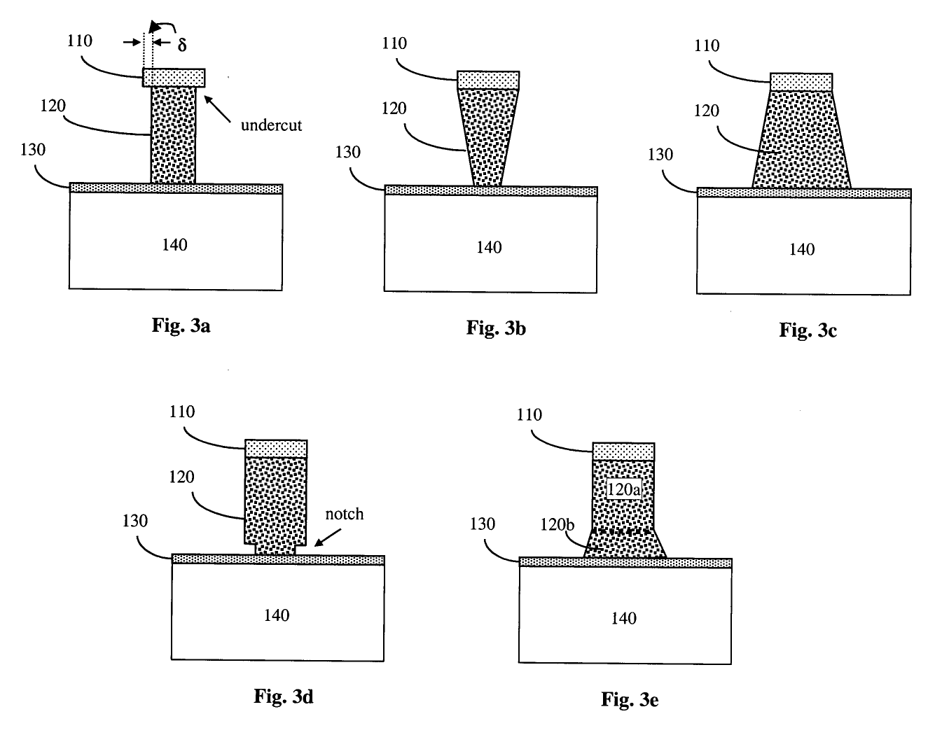

In one embodiment of the present invention, the process gas for the first main etch step 102 includes a base gas and an additive gas. The base gas includes gaseous components typically used in a conventional polysilicon etching process. In a frequently employed embodiment, the base gas includes HBr, Cl₂ and O₂. The Cl₂ gas functions as the main etchant for etching the polysilicon layer 120. In the plasma, part of the Cl₂ gas is energized to form chlorine ions and neutral radicals that react with silicon to form volatile SiClₓ species. Although Cl₂ is more often used, other chlorine-containing gases, such as HCl, BCl₂, may be used in addition to or in place of Cl₂ to perform the functions of Cl₂ in the polysilicon etching process. Without other gaseous components in the process gas, the etching caused by Cl₂ or the chlorine-containing gases has a large isotropic component, resulting in undercutting of the polysilicon layer 120 under the hard mask 110 and a CD bias of (−□, as shown in FIG. 3a.

The HBr gas also contributes to the etching of the polysilicon layer 120. It is believed that the HBr gas helps with the formation of a sidewall passivation layer that promotes anisotropic etching. The O₂ gas is provided to increase the etching selectivity ratio for etching polysilicon relative to silicon dioxide. The O₂ gas may be introduced into the process chamber 202 separately, or it may be introduced into the process chamber 202 together with an inert gas, such as helium, xenon, argon, or krypton. The inert gas serves as a dilutant to help control the volumetric flow rate of O₂ when a very small amount of the O₂ gas is needed.

In one embodiment of the present invention, the additive gas in the process gas in the first main etch step 102 includes NF₃. The NF₃ gas serves several purposes. First, the NF₃ gas contributes fluorine radicals that help to reduce oxide deposition onto the chamber wall, making the process cleaner compared to conventional fluorine-free polysilicon etching processes. Second, the NF₃ gas molecules and/or the fluorine radicals therefrom react with HBr and/or hydrogen radicals dissociated from the HBr gas molecules to form HF and unsaturated NFₓ species (x=0, 1, or 2), which passivate the polysilicon sidewalls and enhance anisotropic etching. These reactions also help to reduce the amount of fluorine radicals in the plasma, resulting in less impact on the polysilicon to oxide etching selectivity compared to conventional etching processes, where CF₄ is added to a Cl₂/HBr/O₂ base chemistry in order to keep the chamber clean. A further advantage of using NF₃ instead of CF₄ is that there is no danger of carbonaceous contamination of the substrate and that there is no fluorocarbon polymer deposition on chamber walls, resulting in the overall cleanliness of the process.

Furthermore, the addition of NF₃ adds another aggressive etchant for silicon-containing materials, such as the polysilicon layer 120 or 160. Therefore, using NF₃ often results in a rapid polysilicon etch rate that is on the order of 1800 to 2500 Å per minute. In addition to the high etch rate, the addition of NF₃ also helps in reducing the microloading of the polysilicon etching process, so that the part of the polysilicon layer 120 near the isolated gate pattern 114 and those near the closely spaced gate patterns 112, as shown in FIG. 1a, are etched at substantially the same etch rate. Moreover, since NF₃ etches differently doped regions in the polysilicon layer 120 at substantially the same rate, the addition of NF₃ often results in reduced N/P loading, i.e., reduced differences in polysilicon etch rate and CD bias between the N-doped region 167 and the P-doped region 168, as shown in FIG. 1c.

To obtain the above advantages, it is important that the ratio of the NF₃ flow rate to the sum of the flow rates of HBr and Cl₂ be kept in a proper range. The proper range of NF₃ to (HBr+Cl₂) flow ratio varies depending on hardware configurations of the etching system used to carry out the polysilicon etching process and on the chemical compositions of the polysilicon layer 120. For a specific application, if the NF₃ to (HBr+Cl₂) flow ratio is too high, tapered polysilicon sidewalls and thus a positive CD bias may result, such as those shown in FIG. 3c. There may also be excessive etching of the oxide hard mask 110 because of the excessive amount of fluorine radicals in the plasma. Conversely, if the NF₃ to (HBr+Cl₂) flow ratio is too low, the aforementioned advantages of adding NF₃ to the process gas are not realized. In one embodiment of the present invention, the NF₃ to (HBr+Cl₂) flow ratio is in the range of 1/20 to 1/5, and more often in the range of 1/10 to 1/6.

In another embodiment of the present invention, the additive gas includes a N₂ gas, which helps to further reduce the N/P loading. Without NF₃, the addition of N₂ to the base gas often results in etched polysilicon sidewalls to have a reentrant profile, such as that shown in FIG. 3b, because N₂ alone does not provide sufficient passivation to combat the largely isotropic etching provided by the Cl₂ gas. Thus, in many applications, especially when the polysilicon layer 120 is dual doped, both NF₃ and N₂ are included in the additive gas during the first main etch step 120. It has been found that N₂ is the most sensitive gas to reduce the N/P loading, while NF₃ is most effective in reducing microloading between dense and isolated areas. By changing the NF₃ to N₂ flow ratio from pure NF₃ to pure N₂, the polysilicon process of the present invention can cover a wide range of doping levels and pattern densities. The proper range of NF₃ to N₂ flow ratio varies depending on specific applications. In one embodiment of the present invention, the NF₃ to N₂ flow ratio is in the range of 0 to 5, and more often in the range of 1 to 2.

Sometimes, more than one main etch step is needed to obtain optimal polysilicon etching profile, especially when doping concentrations in the polysilicon layer 120 vary vertically. As shown in FIG. 1e, dopants are often implanted into an upper part 120a of the polysilicon line 120, and an annealing process that causes the dopants to diffuse into a lower part 120b of the polysilicon line is often not performed until after the polysilicon etching process. As a result, the upper part 120a of the polysilicon line contains significantly higher concentrations of the dopants than the lower part 120b. A transition interface 120i between the upper part and the lower part of the polysilicon layer is usually about 800 Å to 1000 Å below a top 120t of the polysilicon layer 120, as shown in FIG. 1e. If only the first main etch step is used and the process is tuned to obtain a vertical sidewall profile above the transition interface 120i, the sidewall profile below the transition interface 120i is often tapered, as shown in FIG. 3e. This bottom tapering is not desirable as it can seriously affect the electrical performance of the devices being fabricated.

To solve the bottom tapering problem, the polysilicon etching process 100 switches to the second main etch step 104 at the time when the first main etch step has etched or almost etched through the upper part 120a of the polysilicon layer so that portions of the lower part 120b of the polysilicon layer are exposed or uncovered. Compared with the first main etch step 102, the second main etch step 104 uses a lower NF₃ to (HBr+Cl₂) flow ratio while maintaining the NF₃ to N₂ flow ratio substantially the same. The NF₃ and N₂ flow rates are decreased to decrease the amount of passivation occurring during the second main etch step. In one embodiment of the present invention, the NF₃ to (HBr+Cl₂) flow ratio during the second main etch step is about 30% to about 90% of the NF₃ to Cl₂ flow ratio during the first main etch step.

The duration of the second main etch step 104 varies depending on specific applications. In one embodiment of the present invention, the second main etch step 104 is terminated before the lower part 120b of the polysilicon layer is completely etched through, and a third main etch step 106 is used to etch a part 120c of the polysilicon layer 120 near the gate oxide, as shown in FIG. 1f. The part 120c of the polysilicon layer 120 is usually about 100-300 Å thick. An advantage of using the third main etch step 106 is associated with the changing selectivity requirements as the etching proceeds through the polysilicon layer 120 toward the gate oxide layer 130. If the etch rate is high and etch rate selectivity is low when the part 120c of the polysilicon layer 120 is being etched, it is relatively easy to etch through the underlying oxide layer accidentally.

Often times, there is a trade-off between the polysilicon sidewall profile and the polysilicon to oxide etching selectivity. For example, if the second main etch step 104 is adjusted to obtain high etching selectivity, it can result in tapered sidewalls, as shown in FIG. 3e, or notches at the interface between the polysilicon layer 120 and the gate oxide layer 130, as shown in FIG. 3d. By using the third main etch step 106 for the part 120c of the polysilicon layer near the gate oxide 130, one can adjust process parameters such as the source power, the bias power, the gas pressure, the gas flow rates, etc., to obtain a lower polysilicon etch rate and a higher polysilicon to oxide etching selectivity. Thus, the second main etch step 104 can be tuned to provide optimal profile control without the selectivity constraint. For this reason, the third main etch step is often referred to as a soft-landing step.

In some applications, when the polysilicon layer 120 is thin or the dopants are implanted deeply into the polysilicon layer 120 so that the transition interface 120i is close to the gate oxide layer, a separate soft landing step is not practical. So, the third main etch step 106 is not performed and the second main etch step 104 is adjusted to provide not only reduced passivation to accommodate the transition to lower dopant concentrations but also reduced polysilicon etch rate and increased polysilicon to oxide selectivity for better endpoint and profile control. For example, the Cl₂ gas in the second main etch step is sometimes taken out of the base gas for improved selectivity to the gate oxide layer, or an HBr/O₂ only process gas is used in the second main etch step.

After the second main etch step 204, the over etch step 206 is often performed to complete the polysilicon etching process. The over etch step 206 has an even slower polysilicon etch rate and an even higher polysilicon to oxide selectivity as compared to the second main etch step 204.

In addition to the process gas composition, the bias power also plays an important role in achieving optimal etching results. Increasing the bias power often results in increased anisotropy. Since the N-doped regions in the polysilicon layer 120 are more easily attacked by neutral etchants and thus have a higher isotropic etching component, increasing the bias power can mitigate the difference in the isotropic etching component between the N-doped and the P-doped regions, resulting in reduced N/P loading. Increasing bias power also helps to obtain more vertical sidewall profiles. On the other hand, higher bias power results in less chemical and more physical etching, resulting in lower etching selectivities, more severe mask erosion, and more likelihood of punching through the gate oxide. Therefore, the bias power should be kept in a proper range for each etch step in the process 100. In one embodiment of the present invention, the bias power in the first main etch step is in the range of 100 W-150 W, the bias power in the second or the third main etch step is in the range of 50 W-100 W, and the bias power in the over etch step is in the range of 50 W-120 W. The bias power in the second or the third main etch step is lower than that in the first main etch step.

Tables I-II lists examples of several process parameters that can be used in each etch step in the process 100. Tables III lists ranges in which the process parameters may be varied in each etch step in the process 100, according to one embodiment of the present invention. Table IV lists results obtained using the exemplary process parameters listed in Tables I-II when etching the polysilicon layer 120.

Because the actual process parameters, such as the RF power, pressure, gas flow rates, etc., are dependent upon the size of the wafer, the volume of the chamber, and on other hardware configurations of the reactor used to practice the present invention, the invention is not limited to process parameters or the ranges recited herein.

While the present invention has been described with reference to a few specific embodiments, the description is illustrative of the invention and is not to be construed as limiting the invention. Various modifications may occur to those skilled in the art without departing from the true spirit and scope of the invention as defined by the appended claims.

TABLE I
Example 1

| Process Parameters | | ME 1 | ME 2 | ME 3 | OE |
|---|---|---|---|---|---|
| Process Gas (sccm) | HBr | 150 | 150 | 200 | 300 |
| | Cl₂ | 40 | 50 | 0 | 0 |
| | O₂ | 7.5 | 3 | 3 | 6 |
| | NF₃ | 25 | 10 | 0 | 0 |
| | N₂ | 25 | 10 | 0 | 0 |

| | | | | |
|---|---|---|---|---|
| Source Power (W) | 300 | 300 | 300 | 350 |
| Bias Power (W) | 120 | 80 | 20 | 60 |
| Chamber Pressure (mTorr) | 7 | 7 | 20 | 70 |
| Wafer Pedestal Temperature | 65 | 65 | 65 | 65 |
| (° C.) | | | | |

TABLE II
Example 2

| Process Parameters | | ME 1 | ME 2 | ME 3 | OE |
|---|---|---|---|---|---|
| Process Gas (sccm) | HBr | 215 | 215 | 200 | 150 |
| | Cl₂ | 55 | 90 | 60 | 0 |
| | O₂ | 11 | 37 | 12 | 3 |
| | NF₃ | 36 | 36 | 0 | 0 |
| | N₂ | 32 | 32 | 0 | 0 |

| | | | | |
|---|---|---|---|---|
| Source Power (W) | 300 | 300 | 350 | 250 |
| Bias Power (W) | 105 | 90 | 40 | 70 |
| Chamber Pressure (mTorr) | 7 | 7 | 25 | 70 |
| Wafer Pedestal Temperature | 60 | 60 | 60 | 60 |
| (° C.) | | | | |

TABLE III
Ranges

| Process Parameters | | ME 1 | ME 2 | ME 3 | OE |
|---|---|---|---|---|---|
| Process Gas | HBr | 100-300 | 100-300 | 100-300 | 100-400 |
| (sccm) | Cl₂ | 20-200 | 20-200 | 0-100 | — |
| | O₂ | 3-20 | 3-20 | 3-20 | 3-100 |
| | NF₃ | 10-50 | 10-50 | — | — |
| | N₂ | 10-50 | 10-50 | — | — |

| | | | | |
|---|---|---|---|---|
| Source Power (W) | 200-800 | 200-800 | 200-600 | 200-800 |
| Bias Power (W) | 90-150 | 80-120 | 20-100 | 50-120 |
| Chamber Pressure | 4-20 | 4-20 | 10-40 | 50-80 |
| (mTorr) | | | | |
| Wafer Pedestal | 40-70 | 40-70 | 40-70 | 40-70 |
| Temperature (° C.) | | | | |

TABLE IV
Results

| | Example 1 | | | Example 2 | | |
|---|---|---|---|---|---|---|
| | ME 1 | ME 2 | OE | ME 1 | ME 2 | OE |
| Etch Rates (Å/min) | 2000 | 1700 | 900 | 2000 | 1700 | 900 |
| Selectivity to Oxide | 20-25 | 20-25 | >>100 | 20-25 | 20-25 | >>100 |
| CD Bias N/P loading | 2-5 nm | | | 2-5 nm | | |
| Etch Rate N/P loading | 4-5% | 4-5% | | 4-5% | 4-5% | |

What is claimed is:

1. A method for etching polysilicon gates, the method comprising the steps of:
flowing a first gas mixture into a plasma reactor containing a substrate with a polysilicon layer formed thereon, the polysilicon layer being masked by a hard mask, the first gas mixture comprising a bromine-containing gas, a chlorine-containing gas, an oxygen-containing gas, and a NF₃ gas; and
maintaining a plasma of the first gas mixture to etch the polysilicon layer; and
wherein flowing the first gas mixture comprises flowing the bromine-containing gas into the plasma reactor at a first volumetric flow rate, flowing the chlorine-containing gas at a second volumetric flow rate, and flowing the NF₃ gas into the plasma reactor at a third volumetric flow rate, the ratio of the third volumetric flow rate to the sum of the first volumetric flow rate and the second volumetric flow rate being in the range of 1:20 to 1:5.

2. The method of claim 1 wherein the gas mixture further comprises a N₂ gas.

3. The method of claim 2 wherein flowing the first gas mixture further comprises flowing the N₂ gas into the plasma reactor at a fourth volumetric flow rate, the ratio of the fourth volumetric flow rate to the third volumetric flow rate being in the range of 0 to 5:1.

4. The method of claim 3, further comprising:
flowing a second gas mixture into the plasma reactor, the second gas mixture comprising a bromine-containing gas, a chlorine-containing gas, an oxygen-containing gas, and NF₃; and
maintaining a plasma of the second gas mixture to etch the polysilicon layer; and
wherein flowing the second gas mixture comprises flowing the bromine-containing gas at a fifth volumetric flow rate, flowing the chlorine-containing gas at a sixth volumetric flow rate, and flowing NF₃ at a seventh volumetric flow rate, the ratio of the seventh volumetric flow rate to the sum of the fifth volumetric flow rate and the sixth volumetric flow rate being less than the ratio of the third volumetric flow rate to the sum of the first volumetric flow rate and the second volumetric flow rate.

5. The method of claim 4 wherein the polysilicon layer includes dopants of one or more kinds and a dopant concentration for each kind of dopants varies with a depth into the polysilicon layer.

6. The method of claim 5 wherein the polysilicon layer comprises an upper part and a lower part, the dopant concentration for each kind of dopants being higher in the upper part than in the lower part, and wherein the second gas mixture is flowed into the plasma reactor after portions of the lower part of the polysilicon layer are exposed to the plasma of the first gas mixture.

7. The method of claim 4 wherein the second gas mixture further comprises N₂.

8. The method of claim 5 wherein flowing the second gas mixture comprises flowing the N₂ gas into the plasma reactor at an eighth volumetric flow rate, the ratio of the eighth volumetric flow rate to the sum of the fifth volumetric flow rate and the sixth volumetric flow rate being smaller than ratio of the fourth volumetric flow rate to the sum of the first volumetric flow rate and the second volumetric flow rate.

9. The method of claim 8 wherein the ratio of the eighth volumetric flow rate to the seventh volumetric flow rate is substantially the same as the ratio of the fourth volumetric flow rate to the third volumetric flow rate.

10. The method of claim 4 wherein the bromine-containing gas comprises one or more of HBr, Br₂, and CH₃Br.

11. The method of claim 4 wherein the chlorine-containing gas comprises one or more of Cl₂ and HCl.

12. The method of claim 4 wherein the oxygen-containing gas comprises one or more of O₂ and He-O₂.

13. The method of claim 4 wherein maintaining the plasma of the first process gas comprises applying a first bias power to the plasma chamber to electrically bias the substrate with respect to the plasma of the first process gas, maintaining the plasma of the second process gas comprises applying a second bias power to the plasma chamber to electrically bias the substrate with respect to the plasma of the second process gas, and the first bias power being greater than the second bias power.

14. The method of claim 1 wherein the polysilicon layer comprises N-doped and P-doped regions that are etched simultaneously.

15. The method of claim 1 wherein the bromine-containing gas comprises one or more of HBr, Br₂, and CH₃Br.

16. The method of claim 1 wherein the chlorine-containing gas comprises one or more of Cl₂ and HCl.

17. The method of claim 1 wherein the oxygen-containing gas comprises one or more of O₂ and He-O₂.

18. The method of claim 1 wherein the bromine-containing gas is HBr and the chlorine-containing gas is Cl₂.

19. A computer readable medium storing therein program instructions that when executed by a computer causes a plasma reactor to etch polysilicon gates on a substrate, the program instructions comprising:
instructions for flowing a first gas mixture into a plasma reactor containing the substrate with a polysilicon layer formed thereon, the polysilicon layer being masked by a hard mask, the first gas mixture comprising a bromine-containing gas, a chlorine-containing gas, an oxygen-containing gas, and a NF₃ gas; and
instructions for maintaining a plasma of the first gas mixture to etch the polysilicon layer; and
wherein the instructions for flowing the first gas mixture comprises instructions for flowing the bromine-containing gas into the plasma reactor at a first volumetric flow rate, flowing the chlorine-containing gas at a second volumetric flow rate, and flowing the NF₃ gas into the plasma reactor at a third volumetric flow rate, the ratio of the third volumetric flow rate to the sum of the first volumetric flow rate and the second volumetric flow rate being in the range of 1:20 to 1:5.

20. The computer readable medium of clam 19 wherein the program instructions further comprise:
instructions for flowing a second gas mixture into the plasma reactor, the second gas mixture comprising a bromine-containing gas, a chlorine-containing gas, an oxygen-containing gas, and a NF₃ gas; and
instructions for maintaining a plasma of the second gas mixture to etch the polysilicon layer; and
wherein the instructions for flowing the second gas mixture comprises instructions for flowing the bromine-containing gas into the plasma reactor at a fifth volumetric flow rate, the chlorine-containing gas into the plasma reactor at a sixth volumetric flow rate, and flowing the NF₃ gas into the plasma reactor at a seventh volumetric flow rate, the ratio of the seventh volumetric flow rate to the sum of the fifth volumetric flow rate and the sixth volumetric flow rate being smaller than the ratio of the third volumetric flow rate to the sum of the first volumetric flow rate and the second volumetric flow rate.
